(19) United States
(12) Patent Application Publication
(10) Pub. No.: US 2015/0097485 A1
(43) Pub. Date: Apr. 9, 2015

(54) METHOD AND APPARATUS FOR PLASMA IGNITION IN HIGH VACUUM CHAMBERS

(71) Applicant: XEI Scientific Inc., Redwood, CA (US)

(72) Inventor: Ronald A. Vane, Redwood City, CA (US)

(73) Assignee: XEI Scientific Inc., Redwood, CA (US)

(21) Appl. No.: 14/048,493

(22) Filed: Oct. 8, 2013

(51) Int. Cl. H01J 37/32

(52) U.S. Cl. CPC H01J 37/32449; H01J 37/32596; H01J 37/32082; H01J 2237/335
USPC 315/111.21

(57) ABSTRACT

A plasma process method and apparatus for use with a vacuum instrument having a vacuum chamber evacuated by an oil free high vacuum pump to a base pressure below about 1 Pa. A gas buffer chamber in fluid communication with the plasma chamber, the gas buffer chamber having a volume about 1/500 to 1/2000 of the volume of the vacuum chamber. A valve between the plasma chamber and the gas chamber permits flow between the gas chamber and the plasma chamber, wherein, upon opening the valve, gas is admitted into the plasma chamber and pressure in the plasma chamber rises temporarily to between about 10 and about 200 Pa and plasma ignition can be obtained when the plasma excitation device is energized simultaneously. A flow restriction between the gas source and the gas chamber has a maximum flow rate therethrough of about 25 sccm. (standard cubic centimeters per minute) or less so that pressure in the plasma chamber remains between about 1 and about 7 Pa after plasma ignition to maintain plasma conduction and to avoid overloading or heating of the high vacuum pump.

### BACKGROUND OF THE INVENTION

1. Field of Invention

The present invention relates to a new method and apparatus to quickly ignite and start a non-equilibrium gas plasma. More particularly, the present invention is directed to such a method and apparatus for use in a high vacuum system that is pumped by a turbo-molecular pump and then after ignition maintains a low flow of working gas through the plasma at rate that does not load and overheat the turbo-molecular pump. The resulting plasma is used to produce from the working gas active species such as neutral radicals, metastables, ions, free electrons, and UV and visible light while the turbo molecular pump continues to operate.

2. Summary of Prior Art

Plasma or a gas excited into electrically conductive ions and electrons is quite useful in plasma processing, producing excited species, producing light, and cleaning hydrocarbon and other contaminants from surfaces of vacuum instruments. It is known that at low vacuum gases become electrically conductive, and it is easiest to excite or ignite plasmas inside vacuum instruments. At atmospheric pressures plasma takes high power or heat to sustain. At high vacuum less than about 0.10 Pa (Pascal) there are not enough free electrons to sustain a plasma with magnetic confinement or other means.

To ignite and maintain a plasma, an electric field excites a gas to create ions and electrons to carry an electric current, and the plasma may emit light and create metastables and radicals. At low gas pressures, typically between 10 and 200 Pa (1 atm or about 100000 Pa), common gases such as air become highly conductive and plasmas are easy to ignite with relatively lower power. These pressures are easy to obtain with common rough vacuum pumps such as rotary vane pumps which are the work horses in the vacuum field. However these pumps have trouble achieving vacuums below 1 Pa.

Many kinds of vacuum instruments operate at pressures below 0.01 Pa. Plasmas may be sustained without a magnetic field in the mid vacuum range between about 10 and 0.1 Pa but are very hard to ignite. To achieve these lower pressures, it is now common to use turbo molecular pumps that can operate in the vacuum range between 5 Pa and 10⁻⁶ Pa. At these low pressures, it is difficult to ignite plasmas in part because of the reduced density of the gas and lack of free electrons. Plasmas not aided by magnetic fields to confine electrons can operate in the upper ends of this pressure range but are difficult to ignite. Complex apparatus and methods may be needed to adjust pressure levels at which plasma can be ignited easily and then re-evacuate the instrument to process pressures. To ignite plasma in mid vacuum, a source of free electrons, an ionization source, a pressure change, or a high electric field is needed, necessitating expensive additions to the instrument.

It is very difficult to ignite the plasma below 10 Pa pressure consistently without an enhancement method. If the pressure is raised to an operating pressure greater than about 15 Pa and then the RF is turned on, the plasma will ignite reliably. The plasma may be ignited at a higher pressure above 15 Pa and the pressure lowered to 4 Pa or less for the cleaning operation. The previous technology used electronic pressure measurement and control to change the pressure between ignition and plasma states of operation or used a higher pressure greater than about 20 Pa so that the same pressure was used for ignition and plasma operation.

The previous technology apparatus described in U.S. Pat. No. 6,105,589 to Vane was designed for use with oil diffusion high vacuum pumps. These pumps could not be exposed to the reactive gases made by the plasma or operated continuously at pressures above 1 Pa. Since year 2000 most electron microscopes have switched to the cleaner turbo molecular pumps (TMPs). These pumps can tolerate higher pressures and flow rates than diffusion pumps. If they are overloaded

they can overheat or suffer mechanical stress if sudden additional gas load is encountered. Maximum flow and pressure specifications vary with manufacturer but gases flow of about 20 to 25 sccm are usually tolerated by modern turbo pumps for periods of 20 minutes or more.

### SUMMARY OF THE INVENTION

The present invention provides a simplified method of igniting a plasma in a high vacuum chamber when the density of gas otherwise is not enough to provide the conductivity to start a plasma with the power applied. The apparatus of the present invention applies a finite pulse of gas into a small plasma chamber attached to the vacuum chamber simultaneously with the application of power into the plasma chamber, resulting in the plasma ignition at a higher pressure followed by the maintenance of the vacuum at a lower pressure governed by a small leak or flow of working gas into the plasma chamber.

The present invention apparatus may comprise a small gas volume located between a gas admission valve on the small plasma chamber and a gas flow restrictor. The restrictor limits the flow of gas into the small gas volume to a set value when the gas admission valve is open. While the gas admission valve is open, pressure in the plasma and vacuum chambers remains at a level that will support plasma maintenance. When the gas admission valve is closed, the pressure in the small gas volume will slowly equalize with the inlet pressure which in most cases will be atmospheric pressure or about 10⁵ Pa.

These improvements result in a cleaning system that is faster and cleans the specimen chamber, stage, and specimen of the analytical instrument such as an electron microscope better than previous arrangements. The result of a cleaner specimen, specimen chamber and stage is that the deposition of hydrocarbon polymer on the scanned area is reduced or eliminated resulting in better measurements.

Another result of cleaner specimen chambers is that the condensation and adsorption of hydrocarbons on detector windows is reduced which allows the passage of more low energy x-rays and electrons through these windows. In other high vacuum systems the removal of carbon results in a lower partial pressure of carbon compounds without the use of baking or long pumping time.

It is an object of the present invention to provide an improved method and apparatus for igniting a plasma in gases at low pressures for plasma processing, excited species production, and cleaning vacuum chambers. In particular, the present invention is concerned with igniting plasma adjacent to the specimen chamber, to clean the specimen stage and a specimen in the vacuum system of an electron microscope or similar analytical instrument using an electron beam such as a scanning electron microprobe instrument or focused ion beam instrument.

It is another object of the present invention to provide a method for cleaning said instruments that can be operated at lower pressures than conventional plasma methods thus alleviating the need to raise the pressure to above 10 Pa.

It is another object of the present invention to provide a cleaning system that is small and that can be mounted on a standard chamber port of the electron microscope without mechanical interference from other devices and parts of the electron microscope.

It is another object of the present invention to provide a plasma cleaning system that can use room air as the source of oxygen to be converted by the plasma into oxygen radicals for oxidative cleaning.

It is an object of the present invention to provide a plasma system that can be operated with other gases such as O₂, N₂, air, Ar, He, H₂O, H, NH₃ and mixtures thereof.

It is an object of the present invention to control the gas flow into a plasma with a single valve that is either open or closed and without using an integrated pressure gauge to monitor pressure. This results in a very simple plasma cleaning system.

It is an object of the present invention to provide a plasma cleaning system that comprises a small RF plasma chamber that can be operated at 50 Watts or less of forward RF power, a gas dosing device to deliver a quantity of reactant gas for plasma ignition and a flow restrictor to limit the gas flow into the plasma once ignited to a low rate that allows continuous plasma operation without pump damage or overheating and gives high plasma cleaning rates and range.

It is yet another general object of the present invention to provide a method for cleaning such instruments that can be operated at pressures less than 10 Pa, thus alleviating the need to maintain the pressure above 10 Pa after plasma ignition.

Another object of the present invention is to eliminate the need for active monitoring of pressure and control of gas flow into the plasma.

### BRIEF DESCRIPTION OF THE DRAWINGS

FIG. 1 is a schematic depiction of the apparatus of the present invention connected to a vacuum chamber.

FIG. 2 is a pressure-and-time diagram showing the relationship of the before chamber pressure, plasma ignition pressure, steady state plasma pressure, and post plasma pressure.

FIG. 3 shows a preferred embodiment with a Hollow Cathode Electron for RF plasma cleaning of electron Microscopes.

FIG. 4 is a graph of the concentration of oxygen radicals as a function of residence time at various pressures using the apparatus and method of the present invention.

### REFERENCE NUMBERS IN FIGS

1 Small plasma chamber
2 Vacuum chamber
4 Vacuum (Turbo Molecular) Pump
6 Valve
8 Gas manifold
10 Gas orifice
12 Gas buffer chamber
14 Gas source
16 Plasma exciter
20 Hollow cathode
22 Impedance matching network
24 Gas valve connector
30 Gas burst point
32 Baseline level
34 Plasma cleaning period
36 Plasma off point
38 Pressure range

### DETAILED DESCRIPTION OF THE INVENTION

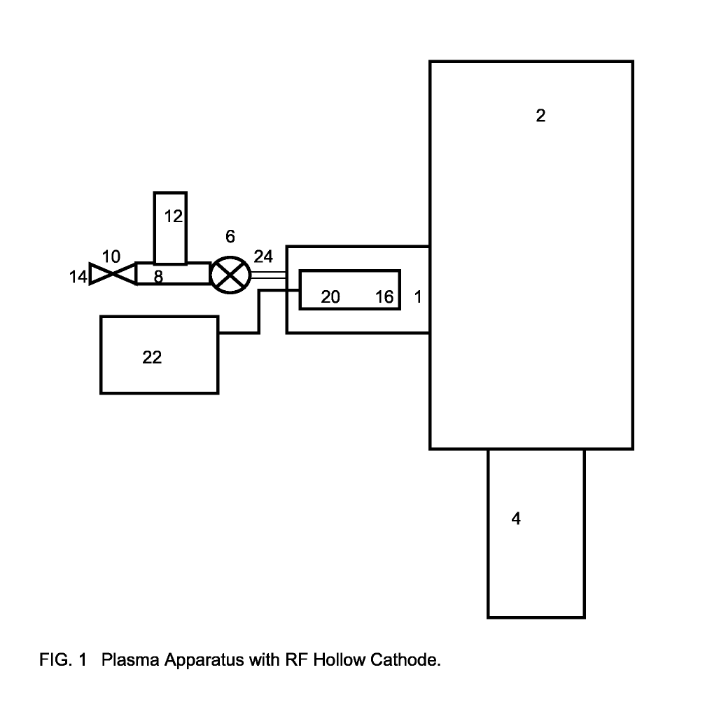

FIG. 1 schematically illustrates the apparatus according to the present invention. A small plasma chamber 1 is attached in fluid communication with the main vacuum chamber 2 of an analytical instrument. As mentioned, the present invention is particularly concerned with the specimen chamber of an electron microscope or similar analytical instrument using an electron beam such as a scanning electron microprobe instrument or focused ion beam instrument. Accordingly, main vacuum chamber 2 is the sample chamber of such an instrument.

Main vacuum chamber 2 is connected to a turbo-molecular pump (TMP) 4, which is used to evacuate or draw a vacuum in chamber 2. An electronically controlled open/close valve 6 is connected to small plasma chamber 1 via a gas valve connector 24 at the end opposite main vacuum chamber 2. Valve 6 controls (in a binary fashion) the flow of a gas into small plasma chamber 1 from a gas manifold 8 and hollow cylindrical gas buffer chamber 12, which is in turn coupled to a flow restriction or restrictor in the form of a needle valve or gas orifice 10, that permits a tiny volume of gas per minute (referred to as a “leak”) to flow into manifold 8 and a gas buffer 12 from a gas source 14. In some instances, the gas can be air, and the source can simply be the atmosphere with proper filtering. The “leak” is an amount or volume flow rate that is sufficiently small that TMP 4 can pump the leaked volume out of main vacuum chamber 2 without overheating, while also providing sufficient gas pressure and volume to permit ignition of the plasma. Preferably, the maximum leak flow rate is no more than about 25 sccm (cc/minute at standard temperature and pressure).

The combined volume of manifold 8 and buffer chamber 12 is about 1/500 to 1/2000 and preferably about 1/1000 the volume of main vacuum chamber 2. Gas buffer 12 and manifold 8 store a volume of gas at approximately atmospheric pressure (higher pressure is undesirable because it would reduce the vacuum in the system too drastically) for “burst” flow into small plasma chamber 1 upon opening of valve 6. An exemplary volume of main chamber 2 is 10 liters, the combined volume of the manifold and buffer chambers preferably is 10 milliliters. The flow rate through flow restriction 10 is preferably about 20 sccm (cc/minute at standard temperature and pressure) for TMPs of small or medium pumping capacity (of less than about 200 1/sec).

The small plasma chamber 1 contains the plasma that is excited electrically using a DC, AC, High frequency, RF, or microwave power source. A plasma igniting or exciting device 16 may be a microwave cavity, contain internal electrodes 20, or be within or adjacent to an ICP (inductively couple plasma) coil, and is energized for plasma ignition or excitation by electric power. An impedance matching network 22 may be needed to match the power source and the load to couple the maximum power into the plasma. The small chamber 1 is directly fluidly connected to main chamber 2 so that the plasma activated gas may flow into the main chamber without restriction.

The method of operation of the present invention includes the steps of pumping the main chamber 2 with the TMP 4 to a vacuum of less than 1 Pa. The plasma is started by turning on the plasma power to plasma exciter or igniter 16 in small plasma chamber 1 simultaneously with the opening of the gas control valve 6. This releases the volume of gas stored in the gas buffer chamber 12 between the input gas valve 6 and the gas leak 10 into the plasma chamber 1 and vacuum chamber 2. This gas is stored at the input gas pressure typically equal to atmospheric pressure (˜10⁵ Pa) when the gas valve 6 is closed. Because the volume of the storage chamber is about 1/1000 the volume of the vacuum chamber, opening the valve 6 will raise the pressure of the vacuum chamber 2 up to about 1/1000 atmospheric pressure (˜50 to 100 Pa) briefly before the gas is removed by TMP 4. Valve 6 remains open while plasma is being generated and while a leak aperture needle valve or orifice 10 supplies gas to plasma chamber 1, but due to its tiny gas throughput, does not allow enough gas flow to overload and overheat the turbo-molecular pump, and keeps the pressure in an operating range of at between about 0.5 and 7 Pa for plasma operation (i.e. maintenance of ignited or excited plasma, once plasma is ignited during the pressure burst it can be sustained at lower pressures).

This burst of gas is of sufficiently long duration and at sufficient pressure to allow the plasma source to ignite the plasma in the small plasma chamber 1. The plasma can then be maintained as TMP 4 re-evacuates the vacuum chambers 2, 1 down to a plasma operating pressure. The pressure will descend to a pressure determined by the leak or flow rate through the leak valve or orifice 10 balanced by the pumping conductance and by the pumping rate of the TMP 4. Typically this pressure will be above about 0.5 to 1 Pa and the plasma operation will be maintained as long as both the plasma power and the gas flow are on. The leak rate of the orifice should be selected to maintain a pressure against the evacuation rate of the vacuum pump that keeps the plasma on and conducting, but low enough that the high vacuum turbo molecular pump is not over heated during the plasma operation time.

The small gas volume is selected such that it is about 1/1000 that of the vacuum chamber. Boyle's law provides that when gas is expanded that P₁V₁=P₂V₂. Thus when the gas in the small gas volume V1 at pressure P1 is expanded into the vacuum chamber volume V2=1000V1 and P2=P1/1000 or about 100 Pa. Because the system is being dynamically pumped and the gas flow is not instantaneous into the plasma chamber the maximum pressure will quickly become less than calculated. However the achieved pressure will probably be above 10 Pa and is enough for easy ignition of the plasma if the RF power is on. If pumping speed is too fast it may be necessary to increase the small volume of gas such that it provides sufficient gas to ignite the plasma.

After plasma ignition, the small gas volume will drop in pressure and will be supplied by gas for the plasma through the gas flow restrictor. The gas flow rate through the restrictor is chosen so that the pressure in the small plasma chamber is above 1 Pa and in the main vacuum chamber below 7 Pa. The 1 Pa minimum in the plasma chamber is chosen because it becomes difficult to maintain plasma conduction without magnetic confinement at below this pressure. The approximate 7 Pa upper limit for the large chamber is caused by the sharp drop in residence time due to the increased collision rates and shorter mean free path that cause a rapid decline in cleaning ability as the pressures rises into the conventional plasma cleaning range. 7 Pa marks the approximate upper pressure of improved cleaning ability of the present invention, and this is the upper limit of the present invention.

There is another upper limit placed on the pressure of about 4 Pa caused by the possible heating of the turbo molecular pump with high higher gas loads. This pressure upper limit varies with the design of the turbo molecular pump. Some Turbo molecular pumps are designed for higher input pressures or flow rates without overheating problems. For these pumps continuous operation a continuous gas load of up to about 25-30 sccm or input pressure of 7 Pa or greater may be tolerated per manufacturer's specification. Small bursts of gas as provided by the present invention are usually tolerated by the turbo molecular pump, but do cause some momentary mechanical stress. This upper limit varies with the model and make of the turbo molecular pump.

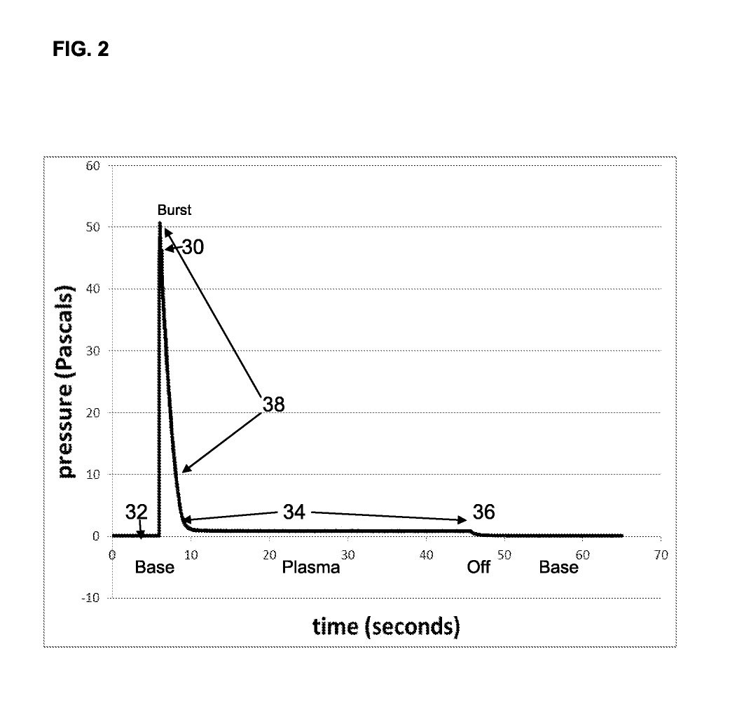

FIG. 2 shows a plot of pressure, time, and period of plasma operation. When the plasma is not needed, both the power and gas (valve 6) are turned off. Before the pressure burst the vacuum is at the baseline level 32 which is typically less than about. 10 Pa when pumped by TMP. When the gas valve 6 (FIG. 1) opens, the gas burst 30 is created in the pressure range 38 typically above 10 Pa and the plasma power is turned on resulting in plasma ignition. The pressure then drops into the plasma cleaning period 34 until the gas flow and plasma power are turned off (by cutting power to plasma exciter 16 and closing valve 6) at point 36. With the gas flow off the pressure will return to the base pressure 32 or below. A lower base pressure will occur if the plasma cleaning process removes contamination that had a significant partial pressure.

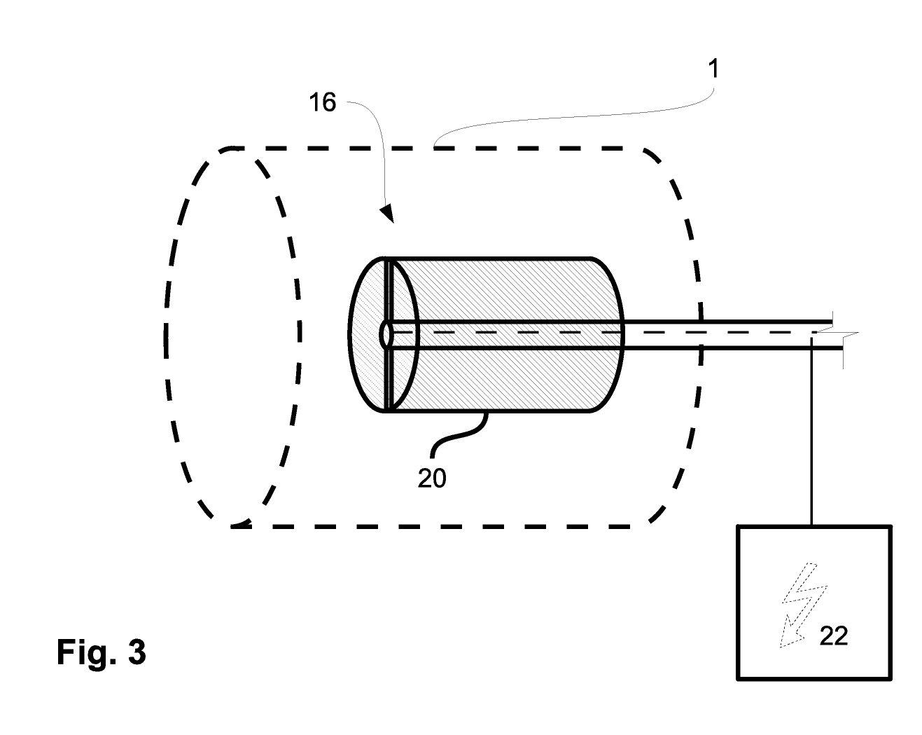

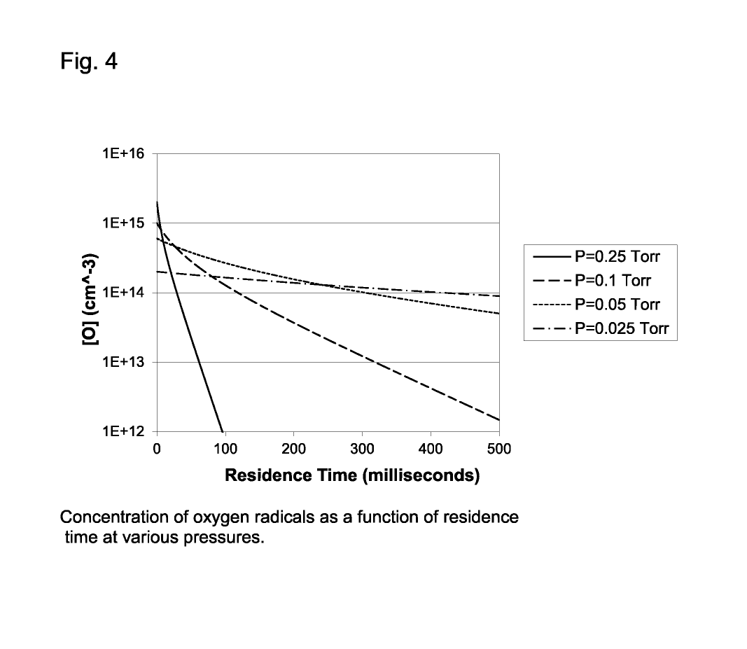

In a preferred embodiment of the present invention, the plasma exciter (16 in FIG. 1) is a hollow cathode RF plasma device as shown in FIG. 3. The resulting plasma is used to produce radicals to clean electron microscopes or other charge beam instruments. The plasma excitation is done by a hollow cylindrical cathode electrode 20 placed inside the small plasma chamber 1 to excite the plasma. The gas source inlet 24 is located (FIG. 1) such that the gas flows inside the hollow cathode cylinder 20. The gas source inlet is connected to the inlet valve 6 and to manifold 8 and baffle 12. RF power is supplied to the hollow cathode 20 in this embodiment. The gas can be air or other oxygen-containing gases or gas mixtures such as oxygen, water vapor, oxygen argon, oxygen and helium, and other nitrogen plus oxygen mixtures for oxidative cleaning. Alternately, hydrogen, hydrogen and nitrogen mixtures, or ammonia-containing gases could be used for reduction cleaning. When the RF power is on, a plasma may be excited inside hollow cathode 20 to produce the desired radicals. The radicals then flow into vacuum chamber 2 which is the imaging chamber of an electron microscope or other instrument that needs to be cleaned. The RF power source is typically 13.56 MHz but other frequencies may be used. An impedance match network 22 will be needed to transfer the maximum power to plasma load. The desired plasma pressure is between about 0.5 Pa and about 7 Pa inside small plasma chamber 1 and differential pumping will result in a lower pressure in the main vacuum chamber. Pumping is done by a TMP 4. This pressure range is desired because there is enough gas density to support sustained plasma and there is a long enough mean free path for long collision free lifetime for the radicals. See FIG. 4 for a chart of O₂ radical lifetimes vs pressure. (Morgan & Vane 2012). Often a flowing afterglow from the decay of metastables and radicals is observed in this pressure range indicating the presence of excited atomic and molecular states. This accompanies the higher cleaning rates and larger cleaning volumes than those obtained at higher pressures. Using quartz crystal monitors there is measureable cleaning measured at 55 cm from the plasma at 20 MTorr while there is almost zero cleaning at this distance at 400 mTorr. It is very difficult to ignite the plasma below 10 Pa pressure consistently without an enhancement method. If the pressure is raised to an operating pressure above about 10 Pa and then the RF is turned on, then the plasma will ignite reliably. The plasma can be ignited at a higher pressure above about 10 Pa and the pressure is then lowered to less than about 7 Pa for the cleaning operation.

The previous technology used electronic pressure measurement and control to change the pressure between ignition and plasma states of operation or used a higher pressure above about 20 Pa to so that the same pressure was used for ignition and plasma operation. In the present invention the plasma power and the gas valve are turned on simultaneously. With a typical vacuum chamber 2 volume of 10 liters, the storage gas volume in the manifold 8 and gas buffer chamber 12 should be about 10 ml. This will provide a burst of gas to ignite a plasma with the pressure rising above 10 Pa temporarily as the RF power turns on. With a typical leak rate of 20 sccm (cubic centimeters/minute at standard pressure and temperature) through the gas leak device and pumping with a typical small-medium sized turbo pump, the pressure will then fall to less than about 7 Pa in the small vacuum chamber and the plasma will be sustained to produce cleaning species.

FIG. 4 shows the concentration of oxygen radicals against residence time at various pressures. The data was calculated in Torr rather than Pa.

Conversion factors:

0.75 Torr=100 Pa

0.25 Torr=33 Pa

0.1 Torr=1.3 Pa

0.05 Torr=6.7 Pa

0.025 Torr=3.3 Pa

Cleaning large chambers with radicals requires that the radicals have long residence time in the chamber so that they can reach locations far away (˜1 m) from the radical source. Destruction of radicals can occur by wall collisions and also by gas phase reactions. These reactions are pressure dependent, especially three-body reactions, which are the most likely means of radical destruction. If the pressure in the chamber is kept low, mean free paths are increased, the three-body reaction rates will be decreased and the residence time of the radicals will increase. This behavior can be demonstrated by a simple kinetics model using literature values for reaction rates. A decrease in pressure leads to a decrease in the number of radicals created by the plasma, but the rate of radical destruction as a function of residence time dramatically decreases. As seen in FIG. 4, at 0.25 Torr chamber pressure, the radical concentration decreases by 1000× in 100 mseconds, but at 0.025 Torr, it will take over 400 milliseconds for the radical concentration to decrease by 2×. Thus lower plasma pressures improve the cleaning ranges and cleaning rates of oxygen radicals.

The invention has been described with reference to preferred embodiments thereof, it is thus not limited, but is susceptible to variation and modification without departing from the scope of the invention.

I claim:

1. A plasma processing apparatus for use with a vacuum instrument having a vacuum chamber of selected volume and said vacuum volume evacuated by a high vacuum pump to a pressure below about 1 Pa, the plasma cleaning apparatus comprising:
a plasma chamber in fluid communication with the vacuum chamber;
a plasma excitation device contained in the plasma chamber;
a gas chamber in fluid communication with the plasma chamber, the gas chamber having a volume about 1/500 to 1/2000 of the selected volume of the vacuum chamber;
a valve between the plasma chamber and the gas chamber, the valve selectively permitting flow between the gas chamber and the plasma chamber;
a gas source in fluid communication with the gas chamber; and
a flow restrictor between the gas source and the gas chamber, the flow restrictor limiting the gas flow into the gas chamber to less than about 25 sccm (standard cubic centimeters per minute) to minimize heating in the vacuum pump, wherein, with the plasma excitation device energized, upon opening the valve, pressure in the plasma chamber rises above about 10 Pa to enable plasma ignition, and gas pressure in the plasma chamber drops to a pressure sufficient to maintain a plasma while the valve remains open admitting gas after plasma ignition.

2. The plasma apparatus of claim 1, wherein the high vacuum pump is a turbo-molecular pump.

3. The plasma apparatus of claim 1, wherein the plasma excitation device is a hollow cathode powered by radio frequency electricity at 13.56 Mz.

4. The plasma apparatus of claim 1, wherein the flow restrictor is an orifice plate.

5. The plasma apparatus of claim 1, wherein the flow restrictor is a needle valve.

6. The plasma processing apparatus of claim 1, wherein the plasma is used for plasma cleaning of the vacuum chamber and surfaces therein.

7. The plasma cleaning apparatus of claim 6, wherein the gas is selected from O₂, N₂, air, Ar, He, H₂O, H, NH₃ and mixtures thereof.

8. The plasma cleaning apparatus of claim 1, wherein the pressure sufficient to maintain a plasma is between about 0.5 Pa and 7 Pa.

9. A method of igniting a plasma in a plasma chamber including a plasma excitation device to operate in a vacuum chamber that is pumped by a high vacuum turbo molecular pump, the plasma chamber being in fluid communication with the vacuum chamber, the method comprising the steps of:
a-selectively admitting a selected volume of gas into the plasma chamber, the selected volume of gas being between about 1/500 and 1/2000 the volume of the vacuum chamber to temporarily raise pressure in the plasma chamber to a level sufficient to aid in the ignition of the plasma;
b-simultaneously with the admitting step, igniting a plasma in the plasma chamber by energizing the plasma excitation device;
c-continuing to flow gas through the plasma chamber at a flow rate less than about 25 sccm (standard cubic centimeters per minute) to maintain an operation pressure range in the plasma chamber sufficient for maintaining the plasma while the plasma excitation device is energized and without overheating the high vacuum pump.

10. The method of claim 9, wherein the operation pressure range is between about 0.5 and 7 Pa.

11. The method of claim 9, wherein the step of igniting plasma comprises energizing a hollow cathode in the plasma chamber with radio frequency electricity at about 13.65 mHz.

12. The method of claim 9, wherein the step of admitting a volume of gas into the plasma chamber comprises opening a valve between the plasma chamber and a gas chamber containing the gas and having a volume between 1/500 and 1/2000 that of the vacuum chamber.

13. The method of claim 9, wherein the gas is selected from O₂, N₂, air, Ar, He, H₂O, H, NH₃ and mixtures thereof.

14. A plasma cleaning apparatus for use with a vacuum instrument having a vacuum chamber of selected volume that may be evacuated by an oil free high vacuum pump such as a turbo-molecular pump to a base pressure below about 1 Pa, the plasma cleaning apparatus comprising:
a plasma chamber in fluid communication with the vacuum chamber;
a plasma excitation device contained in the plasma chamber;
a gas chamber in fluid communication with the plasma chamber, the gas chamber having a volume about 1/500 to 1/2000 of the selected volume of the vacuum chamber;
a valve between the plasma chamber and the gas chamber, the valve selectively permitting flow between the gas chamber and the plasma chamber, wherein, upon opening the valve, gas is admitted into the plasma chamber and pressure in the plasma chamber rises temporarily to above about 10 PA so plasma ignition can be obtained when the plasma excitation device is energized,
a gas source in fluid communication with the gas chamber; and
a flow restriction between the gas source and the gas chamber, the flow restriction having a maximum flow rate therethrough of about 25 sccm. (standard cubic centimeters per minute) so that pressure in the plasma chamber remains sufficient after plasma ignition to maintain plasma conduction and to avoid overloading or heating of the high vacuum pump.

15. The plasma cleaning apparatus of claim 14, wherein the plasma exciter is a hollow cathode powered by radio frequency electricity at 13.56 Mz.

16. The plasma cleaning apparatus of claim 14, wherein the flow restrictor means is an orifice plate.

17. The plasma cleaning apparatus of claim 14, wherein the flow restrictor means is a needle valve.

18. The plasma cleaning apparatus of claim 14, wherein the gas is selected from O₂, N₂, air, Ar, He, H₂O, H, NH₃ and mixtures thereof.

19. The plasma cleaning apparatus of claim 14, wherein pressure is maintained in the plasma chamber between about 0.5 Pa and about 7 Pa after plasma ignition.
